(19) United States
(12) Patent Application Publication
(10) Pub. No.: US 2007/0030032 A1
(43) Pub. Date: Feb. 8, 2007

(54) Fault Tolerant NAND Gate Circuit

(76) Inventor: Chin Lee, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/161,429

(22) Filed: Aug. 3, 2005

(51) Int. Cl. H03K 19/094

(52) U.S. Cl. 326/112

(57) ABSTRACT

A fault tolerant NAND gate circuit includes at least four parallel PMOS transistor and a pair of two serial NMOS transistor. The sources of two NMOS transistor among the four NMOS transistor are coupled to the output of the claimed NAND gate circuit. The claimed fault tolerant NAND gate circuit can avoid fatal errors caused by short or open circuits of adopted MOS transistor effectively.

### BACKGROUND OF THE INVENTION

1. Field of the Invention

The present invention relates to a NAND gate circuit, and more particularly, to a NAND gate circuit that can tolerate faults and has high reliability.

2. Description of the Prior Art

NAND gate circuits are extensively applied in almost every field. Please refer to FIG. 1. FIG. 1 shows a symbol diagram of a NAND gate 100. The output is at low potential level (digital 0) only when both of the two inputs Input1 and Input2 are at high potential level (digital 1). The truth table for the NAND gate in FIG. 1 is listed in FIG. 2. Please refer to FIG. 3. A diagram of the conventional NAND gate circuit in transistor level is illustrated in FIG. 3. PMOS (P-type metal-oxide-semiconductor) transistor p31 and p32 are coupled in parallel. One of the gates of the two PMOS transistors receives a first input signal Input1, and another receives the second input Input2. NMOS (N-type metal-oxide-semiconductor) transistor n31 and n32 are coupled in series. The gate of the NMOS transistor n31 receives the second input signal Input2, the source of the NMOS transistor n31 is connected to ground. The drain of the NMOS transistor n32 is connected to the drains of the two PMOS transistor p31 and p32. The gate of the NMOS transistor n32 receives the first input signal Input1, and the drain of the NMOS transistor n31 is coupled to the source of the NMOS transistor n32. The output of the NAND gate 300 is at the drains of the two PMOS transistor, that is, the drain of the NMOS transistor n32.

However, the NAND gate 300 cannot function correctly if any of the four MOS transistors fails. The yield and reliability of the circuit systems that adopt the NAND gate decrease accordingly.

### SUMMARY OF THE INVENTION

This invention provides a fault tolerant NAND gate circuit for performing NAND operation on two inputs.

Briefly described, the claimed invention discloses a fault tolerant NAND gate circuit for performing NAND operation on a first input and a second input. The fault tolerant NAND gate circuit comprises an output for outputting a result of the NAND operation, an output for outputting a result of the NAND operation, a first PMOS transistor having a source coupled to a first voltage and a gate coupled to the first input, a second PMOS transistor having a source coupled to the first voltage and a gate coupled to the second input, a third PMOS transistor having a source coupled to the first voltage and a gate coupled to the first input, a fourth PMOS transistor having a source coupled to the first voltage and a gate coupled to the second input, a first NMOS transistor having a source coupled to a second voltage and a gate coupled to the second input, a second NMOS transistor having a drain coupled to the output and a gate coupled to the first input, a third NMOS transistor having a source coupled to the second voltage and a gate coupled to the second input, and a fourth NMOS transistor having a drain coupled to the output and a gate coupled to the first input. The drains of the first PMOS transistor, the second PMOS transistor, the third PMOS transistor and the fourth PMOS transistor are coupled to the output. A source of the second NMOS transistor is coupled to a drain of the first NMOS transistor, and a source of the fourth NMOS transistor is coupled to a drain of the third NMOS transistor.

The claimed invention also discloses a fault tolerant NAND gate circuit for performing NAND operation on a first input providing a first input signal and a second input providing a second input signal. The fault tolerant NAND gate circuit comprises an output for outputting a result of the NAND operation, a first PMOS circuit, a second PMOS circuit, and a NMOS circuit. The first PMOS circuit bridges the output and a first voltage when the first PMOS circuit received a high potential signal from the first input, and the second PMOS circuit bridges the output and a first voltage when the second PMOS circuit received a high potential signal from the second input. The first NMOS circuit bridges the output and a second voltage when the first NMOS circuit received a low potential signal from the first input and a low potential signal from the second input.

In the abovementioned fault tolerant NAND gate circuit, the first PMOS circuit comprises two PMOS transistors coupled in serial. The gates of the two PMOS transistors in the first PMOS circuit are coupled to the first input. The second PMOS circuit comprises two PMOS transistors coupled in serial. The gates of the two PMOS transistors in the second PMOS circuit are coupled to the second input. The first NMOS circuit comprises two NMOS transistors coupled in serial. A gate of the first NMOS transistor is coupled to the first input and a gate of the second NMOS transistor is coupled to the second input.

The abovementioned fault tolerant NAND gate circuit further discloses a third NMOS transistor and a fourth NMOS transistor coupled with the first NMOS transistor and the second NMOS transistor in serial. The gate of the third NMOS transistor is coupled to the first input and the gate of the fourth NMOS transistor is coupled to the second input to prevent a fault on the first NMOS transistor or a fault on the second NMOS transistor.

The abovementioned fault tolerant NAND gate circuit further discloses a second NMOS circuit bridging the output and the second voltage to prevent the faults on the whole first NMOS circuit.

The abovementioned fault tolerant NAND gate circuit further discloses a third PMOS circuit and a fourth PMOS circuit bridging the output and the first voltage. The first PMOS circuit has the same structures as the first PMOS circuit to prevent the faults on the whole first PMOS circuit. The second PMOS circuit has the same structure as the second PMOS to prevent the faults on the whole second PMOS circuit.

It is an advantage of the claimed invention that most open circuits or short circuits of the adopted MOS transistors will no more break the present invention fault tolerant NAND gate circuit. The testing of the function of adopted MOS transistors becomes easier as well.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a symbol diagram of a NAND gate circuit.

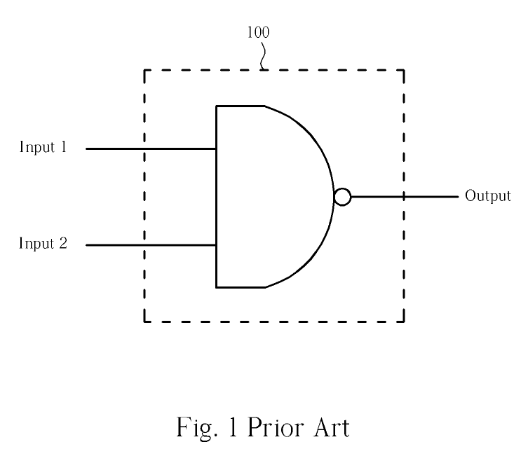

FIG. 2 is a truth table for the NAND gate

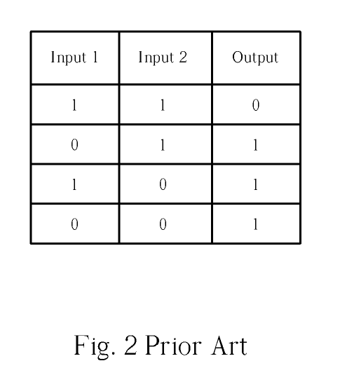

FIG. 3 is a diagram of a NAND gate circuit of the prior art in transistor level.

FIG. 4 is a diagram of a first embodiment of the present invention fault tolerant NAND gate circuit.

FIG. 5 is a diagram of a second embodiment of the present invention fault tolerant NAND gate circuit.

FIG. 6 is a diagram of a third embodiment of the present invention fault tolerant NAND gate circuit.

FIG. 7 is a diagram of a fourth embodiment of the present invention fault tolerant NAND gate circuit.

FIG. 8 is an illustration of a layout choice of some adopted PMOS transistors in the fourth embodiment of the present invention fault tolerant NAND gate circuit.

FIG. 9 is an illustration of a layout choice of some adopted NMOS transistors in the fourth embodiment of the present invention fault tolerant NAND gate circuit.

### DETAILED DESCRIPTION

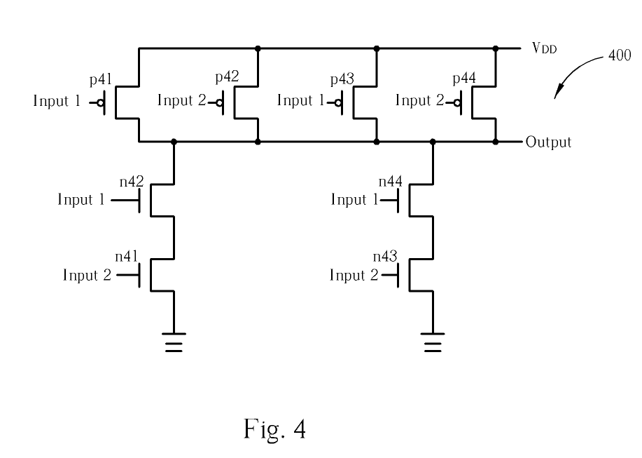

The claimed invention provides a fault tolerant NAND gate circuit that error functions caused by a single short circuit or open circuit within the claimed NAND gate circuit can be corrected. Please refer to FIG. 4. FIG. 4 is a diagram of a first embodiment 400 of the present invention fault tolerant NAND gate circuit. The present NAND gate circuit 400 adopts four PMOS transistors and four NMOS transistors. The sources of the four PMOS transistor p41 to p44 are coupled to a voltage source V_{DD}. The gates of the PMOS transistors p41 and p43 receive the first input Input1, while the gates of the PMOS transistors p42 and p44 receive the second input Input2. The drains of the four PMOS transistors are coupled to the output of the present NAND gate circuit 400. The sources of the NMOS transistors n41 and n43 are coupled to ground, and the gates of the NMOS transistors n41 and n43 are coupled to the second input Input2. The NMOS transistor n42 has a source coupled to the drain of the NMOS transistor n41, a gate coupled to the first input Input1, and a drain coupled to the output of the present NAND gate circuit 400. The NMOS transistor n44 has a source coupled to the drain of the NMOS transistor n43, a gate coupled to the first input Input1, and a drain coupled to the output of the present NAND gate circuit 400. When the PMOS transistor p41 is open, the present NAND gate circuit 400 will not fail since the PMOS transistor p43 still works. Similarly, the present NAND gate circuit 400 can function correctly when any other single PMOS transistor, that is, the PMOS transistor p42, p43 or p44, is open. For the NMOS transistor, the situation is very much alike. If the NMOS transistor n41 is open, the present NAND gate circuit 400 will not fail since the NMOS transistor n43 still works. The present NAND gate circuit 400 functions without error when both of the NMOS transistors n41 and n42 are working normally or both of the NMOS transistors n43 and n44 are working normally.

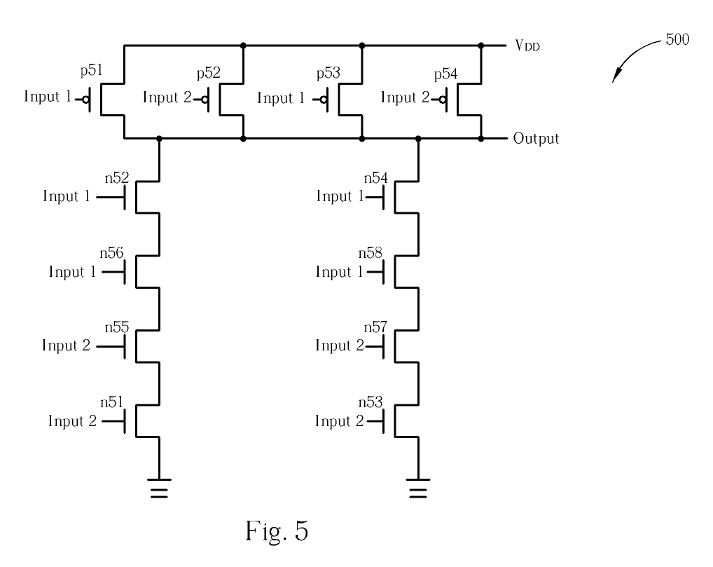

Please refer to FIG. 5. FIG. 5 is a diagram of the second embodiment 500 of the present invention. The present invention fault tolerant NAND gate circuit 500 adapts two additional NMOS transistors in each series of NMOS circuits as illustrated in FIG. 5. In other words, a NMOS circuit comprises the NMOS transistor n51, n52, n55, and n56 coupled in serial, and another NMOS circuit comprises the NMOS transistor n53, n54, n57, and n58 coupled in serial. The serial connection of the NMOS circuits is a benefit to the NAND gate circuit 500 because a short happened on any one of the NMOS transistors will not break the whole NAND gate circuit 500 since other NMOS circuit still work.

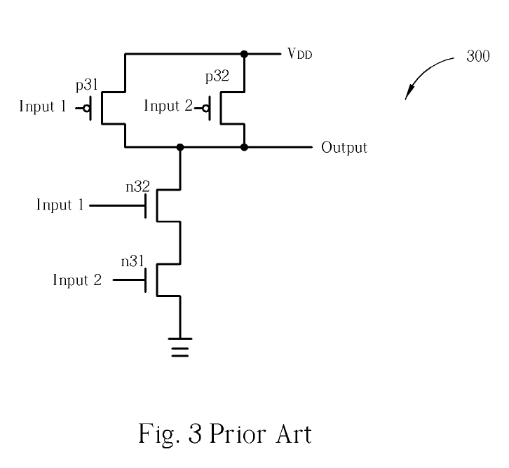

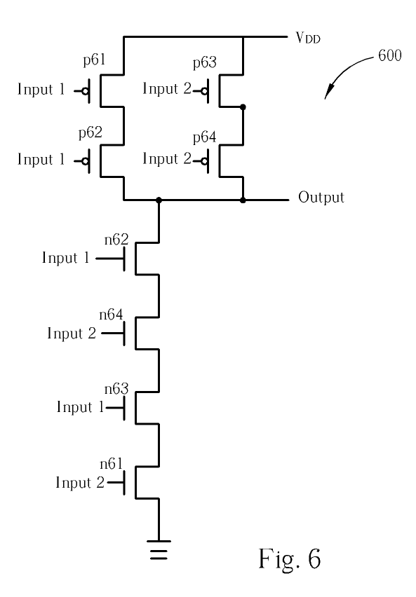

Please refer to FIG. 6. FIG. 6 is a diagram of the third embodiment 600 of the present invention fault tolerant NAND gate circuit. Compared to the conventional fault tolerant NAND gate circuit 300 illustrated in FIG. 3, there are two more PMOS transistors and two more NMOS transistors adopted in the fault tolerant NAND gate circuit 600 as shown in FIG. 6. Each of the four PMOS transistor p61, p62, p63 and p64 is connected with another PMOS transistor in series. Therefore, for example, when the PMOS transistor p61 is stock, i.e. short to digital 1 or 0, the present NAND gate circuit 600 will not fail since the additional PMOS transistor p62 still functions correctly. That means the function of the present NAND gate circuit 600 remains correct no matter the PMOS transistor p61 or other single PMOS transistor among the PMOS transistor p62 to p64 is open or short. Even more, the present NAND gate circuit 600 can function correctly unless both of the PMOS transistors p61 and p62 or both of the PMOS transistors p63 and p64 are open. Further, the embodiment 600 remains the advantage of NMOS circuit that is mentioned in FIG. 5.

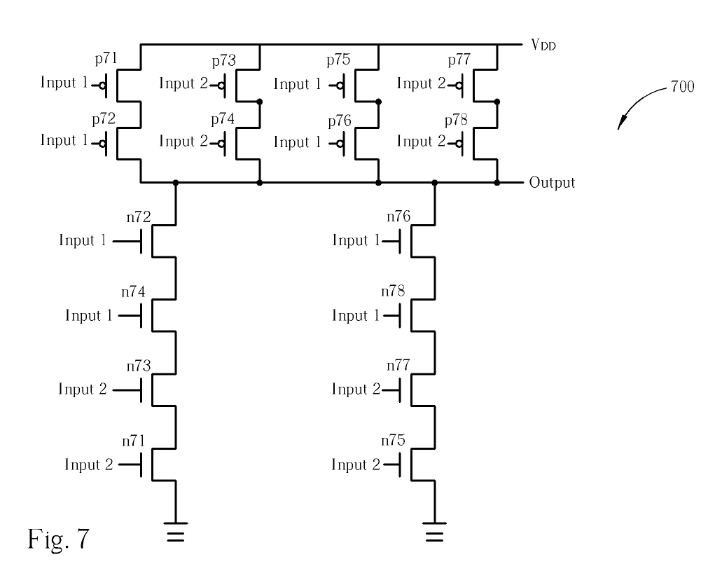

Gaining a NAND gate circuit all advantages above, a fourth embodiment of the present invention NAND gate circuit 700 is designed as shown in FIG. 7. The NAND gate circuit 700 could be seen as a parallel connection of two NAND gate circuits 600. The Most fatal errors caused by short circuits or open circuits of MOS transistor are released. Besides, some fails caused by error input signals can be calibrated in the present invention of fault tolerant NAND gate circuit as well. Take the present invention of fault tolerant NAND gate circuit 700 for example. When the input signal Input1 is 0 and Input2 is 1, the output will be 1 theoretically. However, if the PMOS transistor p75 or the NMOS transistor n76 receives a digital 1 instead of 0, the output is still 1. Further, the characteristic of fault tolerance can be utilized to detect faults in adopted MOS transistor. For example, the output of the claimed NAND gate circuit 700 is 1 when the input signal Input1 is 0 and Input2 is 1 even when the PMOS transistor p75 couples to digital 1 instead of 0 by mistake. However, the situation holds only when all MOS transistor function correctly. If one or more MOS transistor among PMOS transistor p75, PMOS transistor p76, NMOS transistor n76 and NMOS transistor n78 breaks, the NAND gate circuit 700 will output 0 or float. That means, if the output of the NAND gate circuit 700 is 0 or floating, we know there is at least one fault among the four MOS transistors: PMOS transistor p75, PMOS transistor p76, NMOS transistor n76 and NMOS transistor n78.

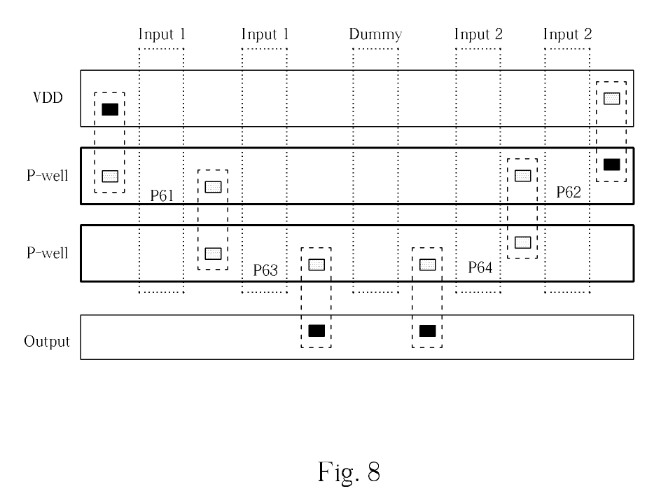

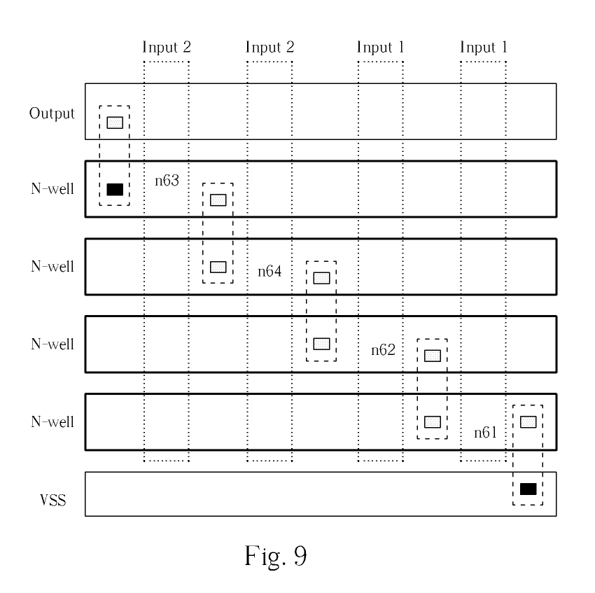

However, if any of the PMOS transistor p72, p74, p76 and p78, or any of the NMOS transistor n72 and n76 (the MOS transistors coupled to the output of the NAND gate circuit) is short to digital 1 or 0, the present invention NAND gate circuit 700 cannot function correctly. This vital drawback can be redeemed by layout skill. Please refer to FIG. 8 and FIG. 9. FIG. 8 is an illustration of a preferred layout choice of the PMOS transistor p61, p62, p63 and p64 in the claimed NAND gate circuit 600, that is, half of the NAND gate circuit 700. The PMOS transistor p61 and p62 adopt different gate lines, and the PMOS transistor p63 and p64 adopt different gate lines Therefore, it is not easy for the input signal lines of the first input signal Input1 to couple to the input signal lines of the second input signal Input2. Further, by the layout shown in FIG. 8, the drains of the PMOS transistor p62 and p64 are released from a short circuit to V_{DD} of the NAND gate circuit 600. FIG. 9 is an illustration of a preferred layout choice of the NMOS transistor n61, n62, n63 and n64. Similarly, the input signal lines for the first input signal Input1 are not easy to couple to the input signal lines for the second input signal Input2. Accordingly, the robustness of the claimed NAND gate circuit is improved further.

The present invention introduces a fault tolerant NAND gate circuit that avoids fatal error caused by short or open circuit of adopted MOS transistor effectively. Related testing methods of utilized MOS transistor according to the inherence of the claimed NAND gate circuit and preferable layout choices are provided as well for reference.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fault tolerant NAND gate circuit for performing NAND operation on a first input and a second input, the fault tolerant NAND gate circuit comprising:
an output for outputting a result of the NAND operation;
a first PMOS (P-type metal-oxide-semiconductor) transistor having a source coupled to a first voltage and a gate coupled to the first input;
a second PMOS transistor having a source coupled to the first voltage and a gate coupled to the second input;
a third PMOS transistor having a source coupled to the first voltage and a gate coupled to the first input;
a fourth PMOS transistor having a source coupled to the first voltage and a gate coupled to the second input;
a first NMOS (N-type metal-oxide-semiconductor) transistor having a source coupled to a second voltage and a gate coupled to the second input;
a second NMOS transistor having a drain coupled to the output and a gate coupled to the first input;
a third NMOS transistor having a source coupled to the second voltage and a gate coupled to the second input; and
a fourth NMOS transistor having a drain coupled to the output and a gate coupled to the first input, wherein the drains of the first PMOS transistor, the second PMOS transistor, the third PMOS transistor and the fourth PMOS transistor are coupled to the output, a source of the second NMOS transistor is coupled to a drain of the first NMOS transistor, and a source of the fourth NMOS transistor is coupled to a drain of the third NMOS transistor.

2. The circuit of claim 1 further comprising:
a fifth NMOS transistor having a source coupled to a drain of the first NMOS transistor and a gate coupled to the second input;
a sixth NMOS transistor having a source coupled to a drain of the fifth NMOS transistor, a gate coupled to the first input, and a drain coupled to a source of the second NMOS transistor;
a seventh NMOS transistor having a source coupled to a drain of the fifth NMOS transistor and a gate coupled to the second input; and
an eighth NMOS transistor having a source coupled to a drain of the seventh NMOS transistor, a gate coupled to the first input, and a drain coupled to a source of the sixth NMOS transistor.

3. A fault tolerant NAND gate circuit for performing NAND operation on a first input and a second input, the fault tolerant NAND gate circuit comprising:
an output for outputting a result of the NAND operation;
a first PMOS transistor having a source coupled to a first voltage and a gate coupled to the first input;
a second PMOS transistor having a source coupled to a drain of the first PMOS transistor, a gate coupled to the first input, and a drain coupled to the output;
a third PMOS transistor having a source coupled to the first voltage and a gate coupled to the second input;
a fourth PMOS transistor having a source coupled to a drain of the third PMOS transistor, a gate coupled to the second input, and a drain coupled to the output;
a first NMOS transistor having a source coupled to a second voltage and a gate coupled to the second input; and
a second NMOS transistor having a drain coupled to the output and a gate coupled to the first input.

4. The circuit of claim 3 wherein a source of the second NMOS transistor is coupled to a drain of the first NMOS transistor.

5. The circuit of claim 4 further comprising:
a fifth PMOS transistor having a source coupled to the first voltage and a gate coupled to the first input;
a sixth PMOS transistor having a source coupled to a drain of the five PMOS transistor, a gate coupled to the first input, and a drain coupled to the output;
a seventh PMOS transistor having a source coupled to the first voltage and a gate coupled to the second input;
an eighth PMOS transistor having a source coupled to a drain of the seventh PMOS transistor, a gate coupled to the second input, and a drain coupled to the output;
a third NMOS transistor having a source coupled to the second voltage and a gate coupled to the second input; and
a fourth NMOS transistor having a drain coupled to the output and a gate coupled to the first input.

6. The circuit of claim 3 further comprising:
a third NMOS transistor having a source coupled to a drain of the first NMOS transistor and a gate coupled to the second input; and
a fourth NMOS transistor having a source coupled to a drain of the third NMOS transistor, a gate coupled to the first input, and a drain coupled to a source of the second NMOS transistor.

7. The circuit of claim 6 further comprising:
a fifth PMOS transistor having a source coupled to the first voltage and a gate coupled to the first input;
a sixth PMOS transistor having a source coupled to a drain of the five PMOS transistor, a gate coupled to the first input, and a drain coupled to the output;
a seventh PMOS transistor having a source coupled to the first voltage and a gate coupled to the second input;
an eighth PMOS transistor having a source coupled to a drain of the seventh PMOS transistor, a gate coupled to the second input, and a drain coupled to the output;
a fifth NMOS transistor having a source coupled to the second voltage and a gate coupled to the second input; and
a sixth NMOS transistor having a drain coupled to the output and a gate coupled to the first input;
a seventh NMOS transistor having a source coupled to a drain of the fifth NMOS transistor and a gate coupled to the second input; and
an eighth NMOS transistor having a source coupled to a drain of the seventh NMOS transistor, a gate coupled to the first input, and a drain coupled to a source of the sixth NMOS transistor.

8. A fault tolerant NAND gate circuit for performing NAND operation on a first input providing a first input signal and a second input providing a second input signal, the fault tolerant NAND gate circuit comprising:
an output for outputting a result of the NAND operation;
a first PMOS circuit bridging the output and a first voltage when the first input signal having a high potential, wherein the first PMOS circuit comprising a first PMOS transistor and a second PMOS transistor coupled in serial and the first input coupling to a gate of the first PMOS transistor and a gate of the second PMOS transistor;
a second PMOS circuit bridging the output and a first voltage when the second input signal having a high potential, wherein the second PMOS circuit comprising a third PMOS transistor and a fourth PMOS transistor coupled in serial and the second input coupling to a gate of the third PMOS transistor and a gate of the fourth PMOS transistor; and
a first NMOS circuit bridging the output and a second voltage when the first input signal having a low potential and the second input signal having a low potential, wherein the first NMOS circuit comprising a first NMOS transistor and a second NMOS transistor coupled in serial, the first NMOS transistor having a gate coupling to the first input and the second NMOS transistor having a gate coupling to the second input.

9. The circuit of claim 8, wherein the first NMOS circuit further comprising a third NMOS transistor and a fourth NMOS transistor coupling in serial, the third NMOS transistor having a gate coupling to the first input and the fourth NMOS transistor having a gate coupling to the second input.

10. The circuit of claim 8 further comprising:
a second NMOS circuit bridging the output and a second voltage when the first input signal having a low potential and the second input signal having a low potential, wherein the second NMOS circuit comprising at least a fifth NMOS transistor and a sixth NMOS transistor coupled in serial, the fifth NMOS transistor having a gate coupling to the first input and the sixth NMOS transistor having a gate coupling to the second input.

11. The circuit of claim 10 wherein the second NMOS circuit further comprising a seventh NMOS transistor and an eighth NMOS transistor coupling in serial, the seventh NMOS transistor having a gate coupling to the first input and the eighth NMOS transistor having a gate coupling to the second input.

12. The circuit of claim 8 further comprising:
a third PMOS circuit bridging the output and a first voltage when the first input signal having a high potential, wherein the third PMOS circuit comprising a fifth PMOS transistor and a sixth PMOS transistor coupled in serial and the first input coupling to a gate of the fifth PMOS transistor and a gate of the sixth PMOS transistor; and
a fourth PMOS circuit bridging the output and a first voltage when the second input signal having a high potential, wherein the fourth PMOS circuit comprising a seventh PMOS transistor and an eighth PMOS transistor coupled in serial and the second input coupling to a gate of the seventh PMOS transistor and a gate of the eighth PMOS transistor.
